(19) United States
(12) Patent Application Publication
(10) Pub. No.: US 2007/0048669 A1
(43) Pub. Date: Mar. 1, 2007

(54) METHOD OF FORMING THE PHOTO RESIST FEATURE

(76) Inventors: Te-Hung Wu, Tainan Hsien (TW); Sheng-Yueh Chang, Taipei Hsien (TW); Chin-Han Wu, Tai-Chung City (TW)

Correspondence Address: NORTH AMERICA INTELLECTUAL PROPERTY CORPORATION, P.O. BOX 506, MERRIFIELD, VA, 22116, US

(21) Appl. No.: 11/162,032

(22) Filed: Aug. 26, 2005

(51) Int. Cl. G03F 7/20

(52) U.S. Cl. 430/311; 430/322

(57) ABSTRACT

The method of forming the photo resist feature comprises forming a photo resist layer on the substrate, providing a photo mask comprises the main feature and the assistant feature, providing the exposure process to form the photo resist main feature and the photo resist assistant feature correspondingly and providing the trimming process to remove the photo resist assistant feature and trim the photo resist main feature. The method reduces OPE and larges the process window.

### BACKGROUND OF INVENTION

1. Field of the Invention

The present invention relates to a photo resist correction method, and more particularly, to a trimming process to remove a photo resist assistant feature.

2. Description of the Prior Art

In semiconductor manufacturing processes, in order to transfer an integrated circuit layout onto a semiconductor wafer, the integrated circuit layout is first designed and formed as a photo mask pattern. The photo mask pattern is then proportionally transferred to a photo resist layer positioned on the semiconductor wafer.

As the design pattern of integrated circuit becomes smaller and due to the resolution limit of the optical exposure tool, optical proximity effect will easily occur during the photolithographic process for transferring the photo mask pattern with higher density. The optical proximity effect will cause defects when transferring the photo mask pattern, such as residue of the assistant feature next to the right angled main feature, right angled corner rounding, line end shortening, and line width increasing/decreasing.

To avoid the mention problems of the optical proximity effect. The photo mask pattern will apply to the optical proximity correction and add the dummy assistant feature to prevent the optical proximity effect. The optical proximity correction is used the computer aided design (CAD) to calculate the deviation firstly, put the correction date into the computer to estimate the photo mask pattern and assistant feature, then output the photo mask pattern and assistant feature which are considered with the optical proximity effect.

Please refer to FIG. 1. FIG. 1 is a diagram of the photo mask pattern exposure process according to the prior art. The photo mask 10 in FIG. 1 comprises the main feature 12 and assistant feature 14 and the semiconductor chip 20 comprises the substrate 21. The photo mask 10 is designed by the circuit (not shown) and consideration of the exposure machine, the optical proximity effect and the assistant feature 14. The computer calculates the ideal photo mask pattern to output the photo mask 10. Currently, the modern exposure machine is projection exposure machine and the modern calculation computer is CAD (computer aided design). Even the main feature 12 is corrected by imitating correction, the designed circuit still is referenced by OPE.

In U.S. Pat. No. 6,777,146 B1, the assistant feature 14 between the main features 12, the pitch between the photo masks and the main feature width have a regular relation. The assistant feature 14 will not expose on the photo resist layer 26, but only the photo resist main feature 22 will show. In general, when the main feature 12 width is 120 μm and the pitch of the photo masks is 320 μm, the assistant feature 14 is less than 50 μm. And the assistant feature 14 will not show on the photo resist layer 26.

However the prior art doesn't have good OPC and the feature after exposure still has residue of the assistant feature next to the right angled main feature, right-angled corner rounded, line end shortened and line width increase/decrease. How to use the assistant feature 14 to develop OPE is an important issue in the domain.

### SUMMARY OF INVENTION

The present invention relates to a method of forming the photo resist feature to solve the above-mentioned problems.

The embodiment according to the present invention providing the method of forming the photo resist feature comprises forming a photo resist layer on the substrate, providing a photo mask comprises the main feature and the assistant feature, providing the exposure process to form the photo resist main feature and the photo resist assistant feature correspondingly and providing the trimming process to remove the photo resist assistant feature and trim the photo resist main feature.

The embodiment according to the present invention providing the method of forming the photo resist feature comprises forming a photo resist layer on the substrate, providing a photo mask comprises the main feature and the assistant feature, providing the exposure process to form the photo resist main feature and the photo resist assistant feature correspondingly and providing the etching process to remove the photo resist assistant feature and trim the photo resist main feature.

The present invention can capacitates bigger assistant feature to reduce OPE and large the process window.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of the photo mask pattern exposure process according to the prior art.

FIGS. 2 to 4 are flowcharts of forming the photo mask pattern according to the present invention.

FIG. 5 is diagram of different assistant feature CD and the main feature pitch relate to the corresponding photo resist main feature width.

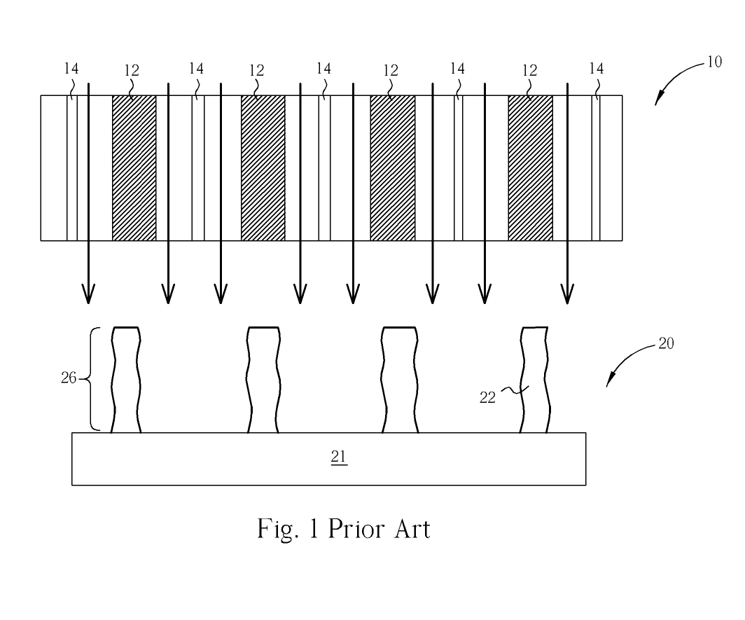

### DETAILED DESCRIPTION

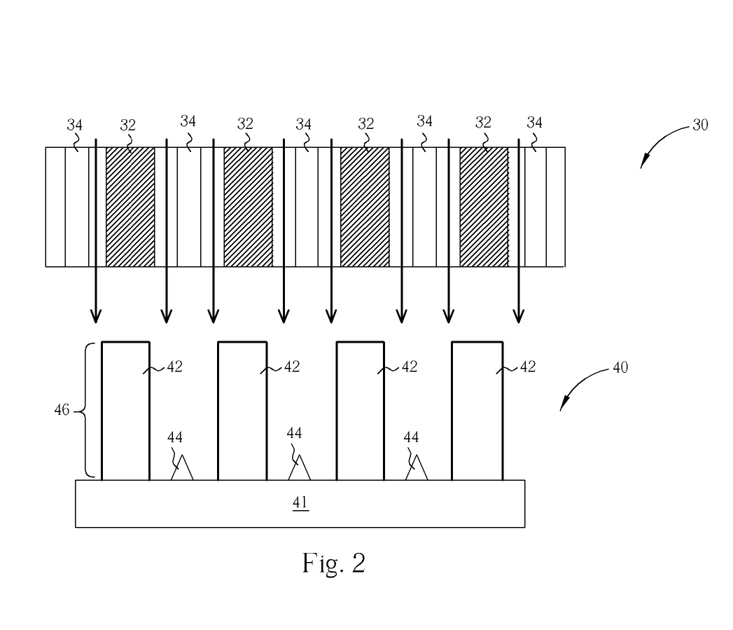

Please refer to FIGS. 2 to FIG. 4. FIGS. 2 to 4 are flowcharts of forming the photo mask pattern according to the present invention. The photo mask 30 in FIG. 2 comprises the main feature 32 and assistant feature 34 which made from serif and scattering bar. The semiconductor chip 40 comprises the substrate 21. The photo mask 30 is designed by the circuit (not shown) and consideration of the exposure machine, the optical proximity effect and the assistant feature 34. The computer calculates the ideal photo mask pattern to output the photo mask30. Currently, the modern exposure machine is projection exposure machine and the modern calculation computer is CAD (computer aided design).

Nevertheless, the correction of the main feature 32 is consideration of the projection, the optical proximity effect correction, the assistant feature 34 and the trimming process correction. The optical proximity effect correction corrects the main feature 32 after OPE. The trimming process correction corrects the photo resist main feature 42 after etching process.

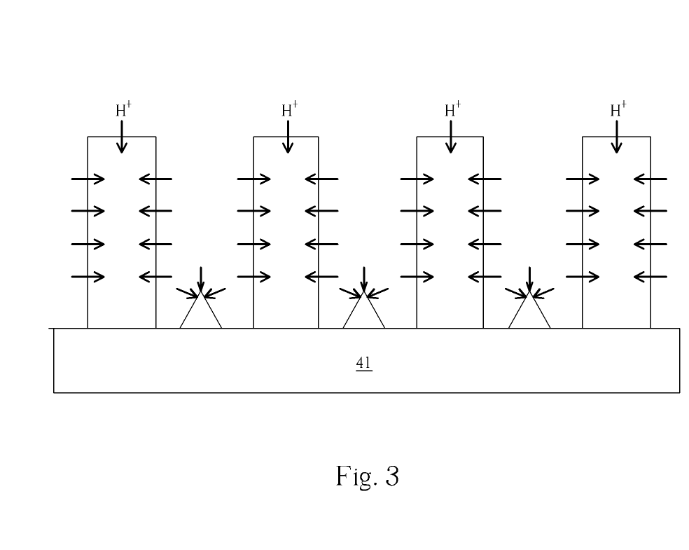

In FIG. 2, the main feature 32 is exposed on the photo resist layer 46 to form the photo resist main feature 42 and the photo resist assistant feature 44. After development process, the substrate only forms the photo resist main feature 42 and the photo resist assistant feature 44. Please refer FIG. 3. The photo resist main feature 42 is etched by the isotropic etching process to form the trimmed photo resist feature 52. The trimmed photo resist feature 52 is similar to the designed circuit on the substrate. The isotropic etching process removes the photo resistant feature 46 also. And the isotropic etching process is the acid liquid. Finally, only the trimmed photo resist feature 52 is on the semiconductor chip 40.

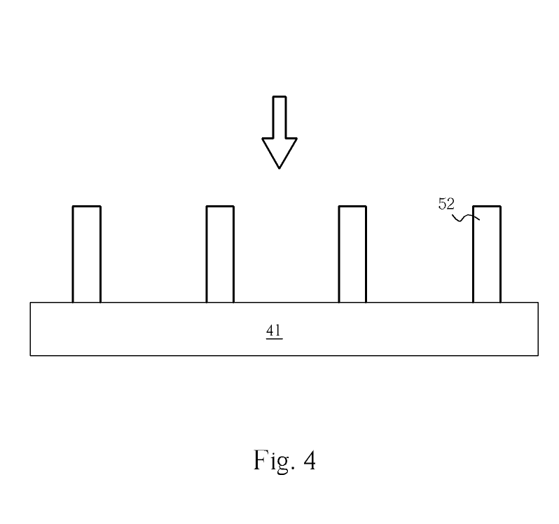

Please refer to FIG. 4. The trimmed photo resist feature 52 is strengthened by the soft backing process. After the development and hard backing process, the trimmed photo resist feature 52 become stronger. Then the designed circuit (not shown) shows on the semiconductor chip 40 after the etching process and the removing photo resist process.

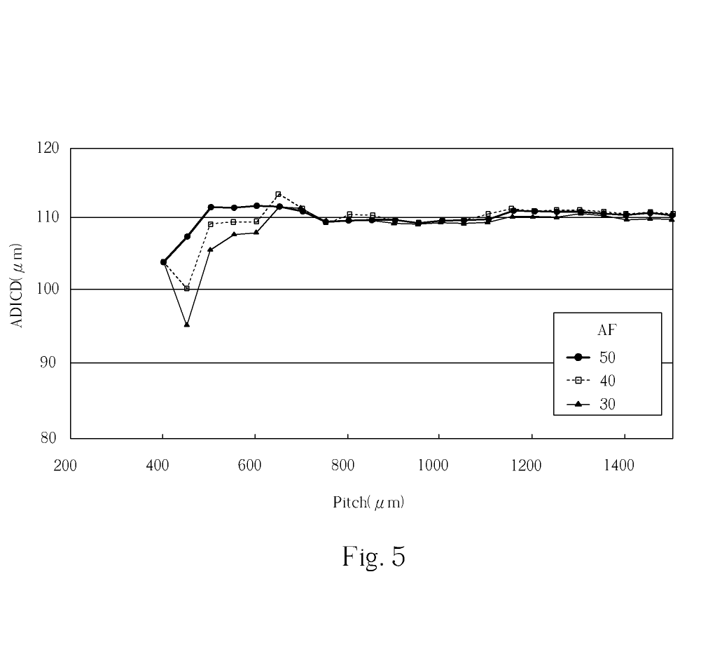

Please refer to FIG. 5. FIG. 5 is diagram of different assistant feature CD and the main feature pitch relate to the corresponding photo resist main feature width. The photo resist main feature is more stable when the pitch is bigger to reduce the residue of the assistant feature next to the right angled main feature, the right-angled corner rounded, line end shortened and line width increase/decrease. Besides, in the dense pitch under 600 μm, the bigger assistant feature has the better ADICD. That is the advantage of the present invention. The present invention uses the assistant feature bigger than sub-resolution feature of the prior art to reduce OPE and large the process window.

The conception of FIG. 5 applies to FIG. 2. When the main feature 32 width is 120 μm and the pitch of the photo masks is 320 μm, the appropriate assistant feature 34 is 70 μm. Compare with the prior art, the present invention can capacitates bigger assistant feature 34 to reduce OPE and large the process window.

Compare with the prior art, the present invention providing a method of forming a photo resist feature on a substrate, the method comprises forming the photo resist feature on the substrate, providing a photo mask and the photo mask comprises at least a first main feature and at least a first assistant feature, providing a exposure process to transfer the first main feature and the first assistant feature on the photo mask to a second main feature and a second assistant feature on the photo resist correspondingly, and providing a trimming process to remove the second assistant feature on the substrate and reduce the second main feature width. The present invention can capacitates bigger assistant feature 34 to reduce OPE, modify the residue of the assistant feature next to the right angled main feature, and large the process window.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a photo resist feature on a substrate, the method comprising:
forming the photo resist feature on the substrate;
providing a photo mask and the photo mask comprises at least a first main feature and at least a first assistant feature;
providing a exposure process to transfer the first main feature and the first assistant feature on the photo mask to a second main feature and a second assistant feature on the photo resist correspondingly; and
providing a trimming process to remove the second assistant feature on the substrate and reduce the second main feature width.

2. The method of claim 1 wherein the first main feature is corrected by an optical proximity correction, which calculates a deviation of an optical proximity effect.

3. The method of claim 2 wherein the optical proximity correction comprises a computer aided design (CAD) to calculate the first main feature.

4. The method of claim 2 wherein the first main feature is corrected by a trimming process correction, which is calculated a bias of the trimming process.

5. The method of the claim 1 wherein the first assistant feature is formed between the first main feature and the adjacent first main feature.

6. The method of the claim 5 wherein the first assistant feature is made of a serif and scattering bar.

7. The method of the claim 1 wherein further comprising a first development process between the exposure process and the trimming process.

8. The method of the claim 1 wherein the trimming process further comprises an etching process to remove the second assistant feature and trim the second main feature.

9. The method of the claim 8 wherein the trimming process further comprises a second development process after the etching process.

10. The method of the claim 8 wherein the second main feature after the etching process is similar to a designed circuit on the substrate.

11. The method of the claim 10 wherein the etching process is an isotropic etching process.

12. The method of the claim 11 wherein the isotropic etching process is made by an acid liquid.

13. A method of forming a photo resist feature on a substrate, the method comprising:
forming the photo resist feature on the substrate;
providing a photo mask and the photo mask comprises at least a first main feature and at least a first assistant feature;
providing a exposure process to transfer the first main feature and the first assistant feature on the photo mask to a second main feature and a second assistant feature on the photo resist correspondingly; and
providing a etching process to remove the second assistant feature on the substrate and reduce the second main feature width.

14. The method of claim 13 wherein the first main feature is corrected by an optical proximity correction, which calculates a deviation of an optical proximity effect.

15. The method of claim 14 wherein the optical proximity correction comprises a computer aided design (CAD) to calculate the first main feature.

16. The method of claim 14 wherein the first main feature is corrected by a trimming process correction, which is calculated a bias of the trimming process.

17. The method of the claim 13 wherein the first assistant feature is formed between the first main feature and the adjacent first main feature.

18. The method of the claim 17 wherein the first assistant feature is made of a serif and scattering bar.

19. The method of the claim 13 wherein further comprising a first development process between the exposure process and the etching process.

20. The method of the claim 19 wherein further comprising a backing process after the etching process.

21. The method of the claim 20 wherein further comprises a second development process after the backing process.

22. The method of the claim 19 wherein the second main feature after the etching process is similar to a designed circuit on the substrate.

23. The method of the claim 13 wherein the etching process is an isotropic etching process.

24. The method of the claim 23 wherein the isotropic etching process is made by an acid liquid.
